(19) United States
(12) Patent Application Publication
(10) Pub. No.: US 2023/0197510 A1
(43) Pub. Date: Jun. 22, 2023

(54) HYBRID METAL INTERCONNECTS

(71) Applicant: INTERNATIONAL BUSINESS MACHINES CORPORATION, Armonk, NY (US)

(72) Inventors: Koichi Motoyama, Clifton Park, NY (US); Oscar van der Straten, Guilderland Center, NY (US); Nicholas Anthony Lanzillo, Wynantskill, NY (US); Alexander Reznicek, Troy, NY (US)

(21) Appl. No.: 17/556,214

(22) Filed: Dec. 20, 2021

(51) Int. Cl. H01L 21/768; H01L 23/528

(52) U.S. Cl. CPC H01L 21/76877; H01L 21/7684; H01L 23/5283; H01L 23/53257

(57) ABSTRACT

Conductive lines, integrated chips, and methods of forming the same include forming a first metal liner in a trench in a substrate. The trench is filled with a second metal. The second metal is overpolished with a chemical mechanical planarization (CMP) process that stops on the first metal liner, such that the second metal is reduced to a level that is below a height of a top surface of the substrate. The trench is filled with a third metal.

### BACKGROUND

The present invention generally relates to semiconductor device fabrication, and, more particularly, to forming hybrid metal interconnects.

As device size in integrated circuits continues to scale down, the use of copper in conductive interconnects may provide high line resistance. This may be due to a relatively large barrier or liner layer that is needed when copper is used, for example to prevent diffusion of the copper into a surrounding material. As the device size shrinks, the thickness of the barrier does not change, and so the barrier takes up proportionally more of the interconnect volume.

### SUMMARY

A method of forming conductive lines includes forming a first metal liner in a trench in a substrate. The trench is filled with a second metal. The second metal is overpolished with a chemical mechanical planarization (CMP) process that stops on the first metal liner, such that the second metal is reduced to a level that is below a height of a top surface of the substrate. The trench is filled with a third metal.

A conductive line includes a first metal liner formed on sidewalls of a trench. A core of a second metal, different from the first metal, is over the first metal liner in the trench. A cap of a third metal, different from the second metal, is formed over the second metal to fill the trench to a height of a surrounding substrate surface.

An integrated chip includes a substrate having a first trench with a first width and a second trench with a second width, the second width being larger than the first width. A first conductive line is in the first trench, the first conductive line having a liner of a first metal and a core of a third metal. A second conductive line is in the second trench, the second conductive line having a liner of the first metal, a core of the second metal, and a cap of a third metal.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the fabrication of hybrid metal interconnects in trenches of varying widths, including narrow trenches, intermediate trenches, and wide wenches, which may all be present in different regions of a device, in accordance with an embodiment of the present invention;

FIG. 2 is a cross-sectional view of a step in the fabrication of hybrid metal interconnects in trenches of varying widths, where a diffusion barrier is conformally deposited in the trenches, including the narrow trench, the intermediate trench, and the wide trench, in accordance with an embodiment of the present invention;

FIG. 3 is a cross-sectional view of a step in the fabrication of hybrid metal interconnects in trenches of varying widths, where a first metal liner is conformally deposited in the trenches, including the narrow trench, the intermediate trench, and the wide trench, in accordance with an embodiment of the present invention;

FIG. 4 is a cross-sectional view of a step in the fabrication of hybrid metal interconnects in trenches of varying widths, where a second metal layer is deposited to fill the trenches, including the narrow trench, the intermediate trench, and the wide trench, in accordance with an embodiment of the present invention;

FIG. 5 is a cross-sectional view of a step in the fabrication of hybrid metal interconnects in trenches of varying widths, where the second metal layer is overpolished to preferentially remove material from narrower trenches, while leaving greater amounts in the wider trenches, in accordance with an embodiment of the present invention;

FIG. 6 is a cross-sectional view of a step in the fabrication of hybrid metal interconnects in trenches of varying widths, where a third metal layer is deposited to fill the trenches, including the narrow trench, the intermediate trench, and the wide trench, in accordance with an embodiment of the present invention;

FIG. 7 is a cross-sectional view of a step in the fabrication of hybrid metal interconnects in trenches of varying widths, where the third metal layer is polished down to form hybrid metal interconnects in the trenches, with differing proportions of metals that depend on trench width, in accordance with an embodiment of the present invention;

FIG. 8 is a block/flow diagram of a method of forming hybrid metal interconnects in trenches of varying widths, with differing proportions of metals that depend on trench width, in accordance with an embodiment of the present invention; and

FIG. 9 is a schematic diagram of a circuit that includes a variety of circuit components, including relatively narrow conductive lines and relatively wide conductive lines, in accordance with an embodiment of the present invention.

### DETAILED DESCRIPTION

Semiconductor device fabrication technologies continue to improve, providing manufacturing processes that have progressively smaller minimum feature sizes. The minimum feature may define things such as the minimum spacing between discrete structures and how small of a structure, such as a trench, may be reliably formed.

One result of this is technological advancement is a decrease in the thickness of the conductive interconnects that devices use to communicate between circuit components, as smaller and smaller device pitch and feature sizes become possible. These low-width interconnects may be used to connect devices to one another on a given chip, and may furthermore be formed on a back-end-of-line (BEOL) layer to provide power and signal communication. While this reduction in size has advantages in the potential device density of a chip, the reduction in size comes with a corresponding increase in interconnect resistance.

The resistance of a conductor, such as a conductive line or wire, can be expressed as R=ρL/A, where ρ is the resistivity of the line material, L is the length of the line, and A is the area of the conductive line. This formula provides an approximation, because factors such as temperature and material defects can further affect the resistance. Because the area A of the conductive line depends on the width of the conductive line, decreasing the width of the interconnect results in a corresponding decrease of the cross-sectional area, and thus causes an increase in the resistance of the conductive line. Higher resistances lead to higher power losses, which translates to higher cooling needs.

The length and cross-sectional area of a given interconnect may be determined by the particular circuit design and fabrication technology being used. For example, some designs may call for shorter, narrower lines in one region, while calling for longer, wider lines in another region. However, the resistivity ρ depends on the selection of material, and a material with a lower resistivity will provide a proportionally lower resistance for the conductive line. As a result, the choice of conductor material can help to offset the increased resistance for smaller width interconnects.

Whereas copper has traditionally been used as a conductor in many circuit applications, due to its low resistivity, other materials also provide low resistivity values, and may not suffer from the same challenges as copper at small scales. For example, copper may need a relatively thick diffusion barrier layer to prevent diffusion into the surrounding material. At small device sizes, this relatively large barrier thickness further decreases the amount of volume in the interconnect that is available for copper conductor, which effectively further decreases the cross-sectional area of the interconnect. Alternative materials may therefore be used in applications where lowered interconnect resistance is desirable at small scales.

Materials such as cobalt, ruthenium, iridium, and rhodium can provide lower resistivities at small device dimensions, despite having higher resistivity values than copper in bulk materials. This may be due to favorable size effects, which result in less scattering than copper at small dimensions. Scattering is an effect that establishes a minimum resistivity of a material, which results from the interactions of electrons with the material. For example, scattering may result from electrons interacting with phonons (quantized vibrations in a material that can act like quasi-particles) or with other electrons in the material, and these scattering effects may provide a significant contribution to the effective resistivity as the width of a copper conductor is decreased. Additionally, these materials may not need barrier or liner layers that are as thick as would be needed for copper lines. The decrease in the liner thickness leaves more space for the conductor and may outweigh copper's bulk resistivity advantage.

In some cases, a given circuit design may call for interconnects having a variety of different line thicknesses. As a result, whereas copper may provide superior resistivity for relatively long and wide lines, another conductive material may provide superior resistance for relatively narrow lines, and may therefore be used instead. However, forming lines with differing types and proportions of conductive materials can be challenging, as increasing the number of masking and deposition steps increases the complexity and cost of the fabrication process and may introduce errors.

To address this, a hybrid line fabrication process may be used that fills narrower trenches with an alternative metal, while the relatively wide trenches may be filled partially with copper and partially with the alternative metal. This provides a single process that forms both types of conductive lines, so that copper can still be used where its lower absolute resistivity may provide an advantage, and can be avoided in narrower lines. This single process can form these different lines without the need for additional masking steps.

To accomplish this, a chemical mechanical planarization (CMP) process may be used to remove a first conductive material from trenches of differing widths. The CMP process may be used to overpolish the trenches. For example, if the first conductive material is a deposited copper layer, the CMP overpolish may remove copper material below a CMP stopping layer. This overpolishing process may remove all of the copper from narrower lines, while only partially removing the copper from the wider lines. The lines of differing widths may then be refilled using the alternative conductor, thereby providing hybrid lines of varying widths that all have good resistance properties.

Referring now to FIG. 1, a cross-sectional view is shown of a step in the fabrication of hybrid metal lines at varying line widths. A substrate 102 is shown, which may be formed from an appropriate dielectric or semiconductor material. A series of line trenches are shown in the substrate 102, including a narrow trench 104, an intermediate trench 106, and a wide trench 108. These trenches may extend in parallel in a direction that is perpendicular to the page, so that the illustrated cross-section shows a full width of the lines.

For example the substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide.

Although not depicted in the present figures, the substrate 102 may also be a semiconductor on insulator (SOI) substrate. In other embodiments, the substrate may include a top surface that is formed from an interlayer dielectric material, such as silicon dioxide. In still other embodiments, a semiconductor substrate may have trenches defined by a layer of dielectric material on top of it.

The substrate 102 may further include any of a variety of devices (not shown) that may be formed in or on the substrate 102, including active circuit components, such as transistors, and/or passive circuit components, such as capacitors, inductors, and resistors. The trenches may intersect other conductive structures, such as vias, device contacts, and other conductive interconnects. These devices may have electrical contacts at a surface of the substrate 102 that may make electrical contact with conductive interconnects that may be formed in the trenches.

The narrow trench 104 may be formed at a width that is at or below a minimum feature size of a fabrication technology (e.g., about 20 nm). For example, in a given photolithographic process, there is a minimum size that can be defined using a given wavelength of light. Additional processing steps may be performed to reduce the trench width further if needed, below the minimum feature size of the fabrication technology, for example by conformally depositing additional material on the trench sidewalls.

In contrast to the narrow trench 104, the wide trench 108 may be formed at a width that is equal to or greater than five times the minimum feature size (e.g., about 100 nm). The intermediate trench 106 may be formed at a width that is between the minimum feature size and about five times the minimum feature size (e.g., between about 20 nm and about 100 nm). Thus, trenches may be formed at a variety of different sizes in accordance with the needs of the circuit design, and these trenches may be further processed, as described herein, to produce conductive interconnects at different respective widths.

The trenches 104 may be formed by any appropriate process, such as a photolithographic process that defines a mask on the substrate 102 using a resist, followed by an anisotropic etch down into the substrate 102. Photolithography may include the patterning of a resist material, which can be cured with exposure to a certain wavelength of light. Uncured portions of the resist material may be removed, so that the underlying substrate can be patterned using an anisotropic etch that selectively removes the underlying material without destroying the mask.

The anisotropic etch may include a reactive ion etch (RIE). RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation.

Although the trenches are shown as being oriented in parallel on the same surface of the substrate 102, it should be understood that trenches may be formed in any position and in any orientation on the substrate 102, for example to connect devices that may be positioned on or in the substrate 102. Additionally, the illustrated spacing between the trenches and the proportions of the trenches should be understood as being purely illustrative. Any other appropriate arrangement of trenches, including trenches of differing widths, directions, and surfaces, is also contemplated as being within the present principles.

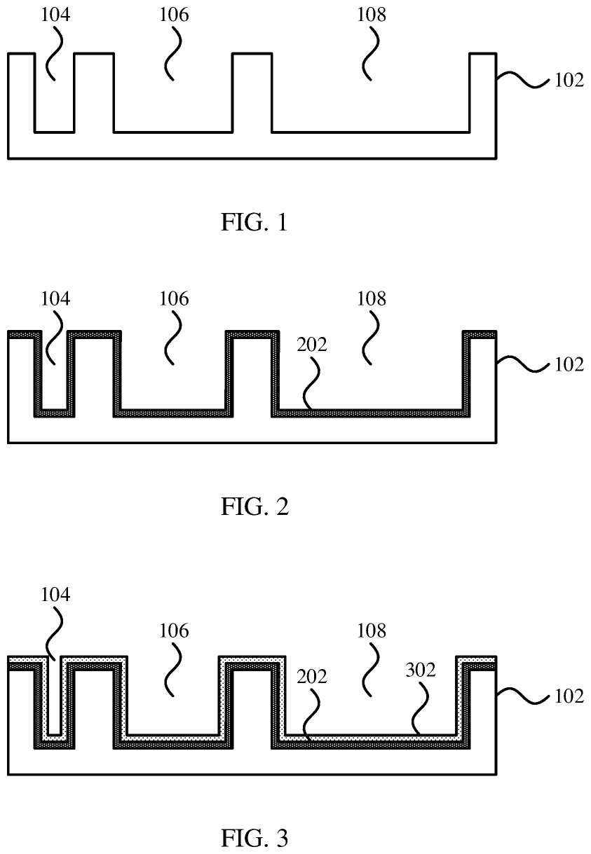

Referring now to FIG. 2, a cross-sectional view is shown of a step in the fabrication of hybrid metal lines at varying line widths. A diffusion barrier 202 is formed on the substrate 102, including on the surfaces in the trenches. The diffusion barrier 202 may be formed using any appropriate diffusion barrier material, such as tantalum nitride, using any conformal deposition process, such as chemical vapor deposition (CVD) or atomic layer deposition (ALD). The diffusion barrier 202 coats the inner surfaces of the trenches and may have an exemplary barrier thickness of between about 1 nm and about 3 nm and may prevent diffusion of conductor atoms into the substrate 102.

CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use ALD, chemical precursors react with the surface of a material one at a time to deposit a thin film on the surface.

Referring now to FIG. 3, a cross-sectional view is shown of a step in the fabrication of hybrid metal lines at varying line widths. A first metal liner 302 is formed on the diffusion barrier 202, including on the surfaces in the trenches. Although any appropriate material may be used, it is specifically contemplated that material of the first metal liner 302 may be formed from a noble metal material. An exemplary thickness of the first metal liner 302 may be between about 1 nm and about 3 nm.

Noble metals are generally understood as being highly resistant to dissolution by chemicals, and may include ruthenium, rhodium, or iridium. Noble metals may have a much lower polishing rate than copper for a given CMP process, especially in lines with small thickness, as the volume fraction of noble metals at the top portion of a trench is larger relative to the fraction of the metal being removed (e.g., copper).

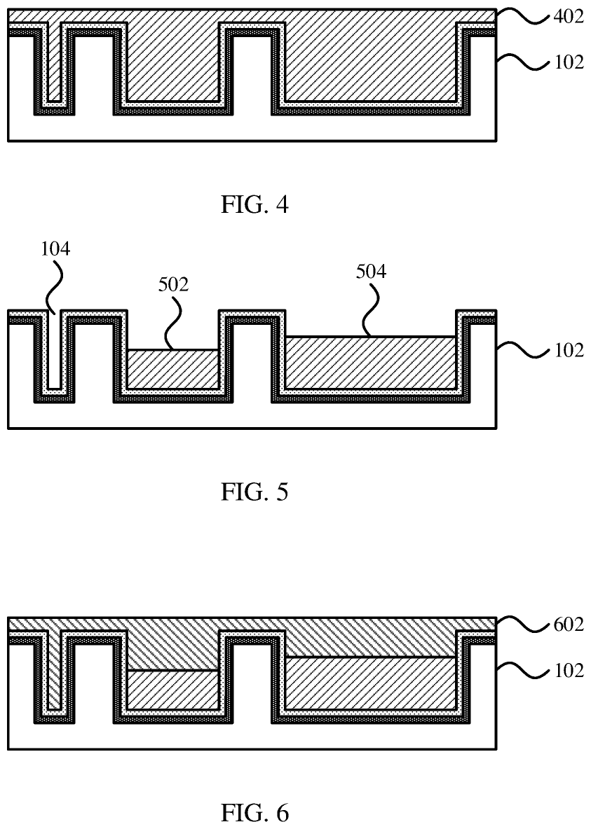

Referring now to FIG. 4, a cross-sectional view is shown of a step in the fabrication of hybrid metal lines at varying line widths. A second metal layer 402 is deposited over the first metal liner 302 using any appropriate deposition process, such as CVD, ALD, or physical vapor deposition (PVD). The second metal layer 402 may be formed from, e.g., copper, at a thickness sufficient to completely fill the trenches. Although copper is specifically contemplated for this layer, it should be understood that any appropriate conductor, different from the material of the first metal liner 302, may be used instead.

Referring now to FIG. 5, a cross-sectional view is shown of a step in the fabrication of hybrid metal lines at varying line widths. A CMP process may be performed that stops on the first metal liner 302. CMP is performed using, e.g., a chemical or granular slurry and mechanical force to gradually remove upper layers of the device. The slurry may be formulated to be unable to dissolve, for example, the material of the first metal liner 302, resulting in the CMP process's inability to proceed any farther than that layer. For example, this CMP process may be unable to dissolve the noble metal of the first metal liner 302.

The CMP may be performed for a period of time after the first metal liner 302 has been exposed, a process which may be referred to herein as an overpolish. Although the extended CMP process will not remove substantially more material from the first metal liner 302, due to the first metal liner 302 being formed from a noble metal that cannot be dissolved by the CMP process, this overpolish will continue to remove material from the second metal layer 402, even below the top surface of the first metal layer.

The longer the overpolish time, the more material will be removed from the second metal layer 402. The rate of removal of material from a trench during the overpolish depends on the width of the trench, so that the second metal in the narrow trenches 104 may be removed completely, while the second metal in the wide trenches 108 may only be reduced in height by a relatively small amount, leaving a substantial amount of the second metal within the intermediate trench 106 and the wide trench 108. In this manner, a single fabrication process can form interconnects having different proportions of, e.g., copper to another conductor, based on the relative widths of the trenches in question.

The CMP may remove copper faster in narrower trench 104 because copper is a smaller percentage of the volume of the trench, relative to the greater widths of the wide trench 108. After the overpolish, the narrow trench 104 may have no second metal remaining, the intermediate trenches 106 may have a moderate amount 502 of second metal remaining, and the wide trenches 108 may have a large amount 504 of second metal remaining. The wide trenches 108 thus may retain most of their volume as copper. The overpolish thereby differentiates between structures of differing widths.

Referring now to FIG. 6, a cross-sectional view is shown of a step in the fabrication of hybrid metal lines at varying line widths. A third metal layer 602 is deposited using any appropriate deposition process, filling the trenches above the second metal. In the intermediate trenches 106 and the wide trenches 108, the third metal layer 602 fills the remaining portion of the trenches above the second metal portions 502 and 504, so that the trenches each have a respective conductor having a different respective proportion of metals. The third metal layer 602 fills the narrow trench 104 completely, because all of the second metal was removed from the narrow trench 104 during the overpolish.

The third metal layer 602 may be formed from any appropriate conductive material, which may have a lower resistivity than copper at small dimensions. For example, the third metal layer 602 may be formed from ruthenium, cobalt, iridium, or rhodium. Although these metals are specifically contemplated, it should be understood that any appropriate conductive material may be used instead. In some cases, the third metal layer 602 may be formed from a same material as the first metal liner 302, whereas in other cases the third metal layer 602 may be formed from a distinct material, forming a distinct cap over the portions of second metal.

An anneal may be performed to reflow the material of the third metal layer 602, such that there are no voids present within the trenches. In the specific example of using cobalt as the material for the third metal layer, the third metal layer 602 may be formed by first depositing a cobalt seed layer using, e.g., PVD or CVD. The trenches may then be filled by plating on the remaining volume of cobalt.

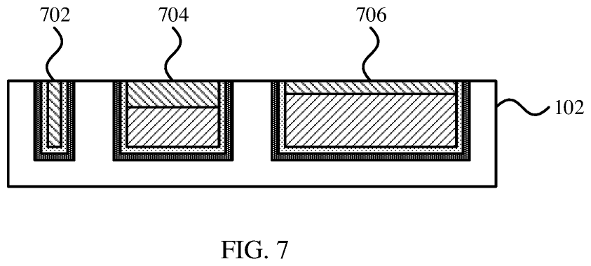

Referring now to FIG. 7, a cross-sectional view is shown of a step in the fabrication of hybrid metal lines at varying line widths. A CMP process is performed that polishes down to the level of the substrate 102, removing material from the third metal layer 602, the first metal liner 302, and the diffusion barrier 202 until the top surface of the substrate 102 is exposed. This CMP process does not overpolish, but instead stops once the material over the substrate 102 has been completely removed.

This CMP process separates out the conductive lines from one another, including narrow line 702, which may be formed entirely from the third metal with a liner of the first metal, intermediate line 704, which may be formed from a moderate amount of the second metal with a liner of the first metal and a moderate cap of the third metal, and wide line 706, which may be formed from a larger amount of the second metal, relative to the intermediate line 704, with a liner of the first metal and a small or nonexistent cap of the third metal. In the event that the first metal and the third metal are formed from the same material (e.g., ruthenium), then the core portion of the intermediate line 704 and the wide line 706, formed from the second metal, may be entirely encapsulated in that material.

In the specific example of using cobalt for the cap layers of the intermediate line 704 and the wide line 706, cobalt has strong adhesion to the underlying copper. As a result, electromigration of the copper due to the passage of current through the conductive lines can be suppressed. Such electromigration can cause long-term damage to conductor structures, as the conductive material is displaced by the current it carries. In some specific examples, the narrow line 702 may have no copper in it, the intermediate line 704 may have greater than 0% but less than 50% copper, while the wide line 706 may have greater than 50% copper.

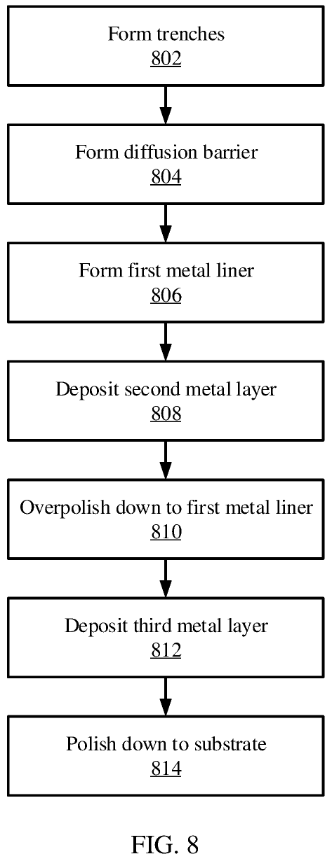

Referring now to FIG. 8, a method of forming hybrid lines of differing widths, with different width lines having different compositions, is shown. Block 802 forms trenches in the substrate 102, including narrow trenches 104, intermediate trenches 106, and wide trenches 108. The trenches may be formed, for example using photolithography to create a pattern mask followed by an anisotropic etch process.

Block 804 forms a diffusion barrier 202 by a conformal deposition process that coats the inner surfaces of the trenches of the substrate 102. The diffusion barrier 202 helps to prevent metal atoms from diffusing into the substrate 102, which could otherwise decrease electrical performance of the conductive lines. Block 806 forms a first metal liner 302 from a noble metal, such as ruthenium, over the diffusion barrier 202 using a conformal deposition process that coats the inner surfaces of the trenches.

Block 808 deposits second metal layer 402 using any appropriate deposition process, completely filling the trenches. The second metal layer 402 may be formed from copper or any other appropriate conductive metal. Block 810 overpolishes the second metal layer 402 using a CMP process that stops on the first metal liner 302, but that is performed for a period of time after the first metal liner 302 is exposed. Additional material from the second metal layer 402 is removed during the overpolish, lowering the level of that layer below the top level of the first metal liner 302. The overpolish empties the trench 104 of the second metal and provides recessed intermediate second metal line 502 and recessed wide second metal line 504.

Block 812 deposits a third metal layer 602, which may be a same metal as the second metal liner 402 or may be a different metal, using any appropriate deposition process. Block 814 polishes down to expose the top surface of the substrate 102 using a CMP process that stops on the substrate material. This polish step separates the third metal layer 602 in the respective trenches, forming narrow conductive lines 702 that may be formed from the third metal with a liner of the first metal, intermediate conductive lines 704 that may have a relatively small core of the second metal, with a bottom and side liner of the first metal and a relatively thick cap of the third metal, and wide conductive lines 706 that may have a relatively large core of the second metal, with a bottom and side liner of the first metal and a relatively thin cap of the third metal.

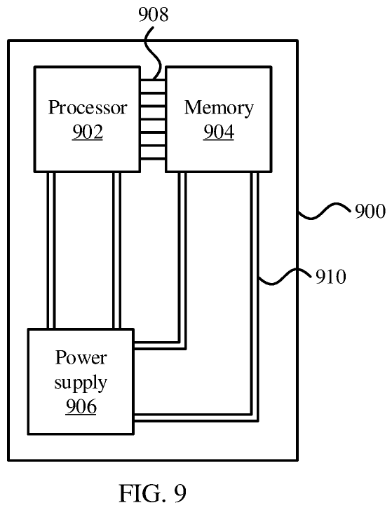

Referring now to FIG. 9, a top-down schematic view of an exemplary circuit 900 is shown. Such circuits may include any of a variety of different circuit components, including active components, such as transistors, and passive components, such as capacitors, inductors, resistors, and transmission lines. The circuit 900 is illustrated as having a variety of different functional components, represented as blocks, which may themselves include a variety of components integrated into respective chips. In some cases, the circuit 900 may be an integrated chip that includes the functional components on a single substrate.

For example, the circuit 900 may include a processor 902 and a memory 904, each of which may be powered by a power supply 906. The processor 902 may include a variety of logic circuits, which may take inputs from the memory 904 and which may provide outputs back to the memory 904. Other types of components that may be included in the circuit include sensors, timing circuits, and input/output circuits.

The processor 902 and the memory 904 may be closely integrated, with relatively dense connections 908 between them. The dense connections 908 may have short lengths and may be closely packed to ensure fast communications with little area sacrificed. Relatively little current may be transmitted on these dense connections 908.

Power connections 910 between the power supply 906 and the processor 902 and memory 904, meanwhile, may have longer lengths and may carry higher levels of current, as the power connections 910 may supply power for multiple circuit components.

The dense connections 908 may therefore be formed with relatively narrow conductive lines, while the power connections 910 may be formed with relatively wide conductive lines. Because the dense connections 908 may be relatively short, and may carry relatively little current, less power is lost in such connections and the need for low resistance is lessened. In contrast, because the power connections 910 may be relatively long and may carry relatively high currents, the lower resistance that is provided by having a greater proportion of copper in the conductive lines may be beneficial to decrease power consumption and heat generation.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative teams are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it ill also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of hybrid metal interconnects (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method of forming conductive lines, comprising:
forming a first metal liner in a trench in a substrate;
filling the trench with a second metal;
overpolishing the second metal with a chemical mechanical planarization (CMP) process that stops on the first metal liner, such that the second metal is reduced to a level that is below a height of a top surface of the substrate; and
filling the trench with a third metal.

2. The method of claim 1, wherein the first metal liner is formed from a noble metal.

3. The method of claim 1, wherein the third metal is a same material as the first metal liner.

4. The method of claim 3, wherein the first metal liner is formed from ruthenium.

5. The method of claim 1, wherein the third metal is a different metal from the first metal liner.

6. The method of claim 5, wherein the first metal liner is formed from ruthenium and the third metal is formed from the group consisting of cobalt, iridium, and rhodium.

7. A conductive line, comprising:
a first metal liner formed on sidewalls of a trench;
a core of a second metal, different from the first metal, over the first metal liner in the trench; and
a cap of a third metal, different from the second metal, formed over the second metal to fill the trench to a height of a surrounding substrate surface.

8. The conductive line of claim 7, wherein the third metal is formed from a same material as the first metal liner.

9. The conductive line of claim 8, wherein the third metal and the first metal liner are formed from ruthenium.

10. The conductive line of claim 7, wherein the third metal is formed from a different material from the first metal liner.

11. The conductive line of claim 10, wherein the first metal liner is formed from ruthenium and the third metal is formed from a material selected from the group consisting of cobalt, ruthenium, iridium, and rhodium.

12. An integrated chip, comprising:
a substrate having a first trench with a first width and a second trench with a second width, the second width being larger than the first width;
a first conductive line in the first trench, the first conductive line having a liner of a first metal and a core of a third metal;
a second conductive line in the second trench, the second conductive line having a liner of the first metal, a core of the second metal, and a cap of a third metal.

13. The integrated chip of claim 12, wherein the third metal is formed from a same material as the first metal.

14. The integrated chip of claim 13, wherein the third metal and the first metal liner are formed from ruthenium.

15. The integrated chip of claim 12, wherein the third metal is formed from a different material from the first metal liner.

16. The integrated chip of claim 15, wherein the first metal liner is formed from ruthenium and the third metal liner is formed from a material selected from the group consisting of cobalt, ruthenium, iridium, and rhodium.

17. The integrated chip of claim 12, wherein the first conductive line includes none of the second metal.

18. The integrated chip of claim 12, further comprising a third conductive line formed in a third trench of the substrate, having a width that is between the first width and the second width, the third conductive line having a liner of the first metal, a core of the second metal, and a cap of a third metal.

19. The integrated chip of claim 18, wherein the core of the third conductive line has a smaller vertical thickness than the core of the second conductive line.

20. The integrated chip of claim 12, wherein the first second width is at least five times larger than the first width.
